(19) United States
(12) Patent Application Publication
(10) Pub. No.: US 2017/0317466 A1
(43) Pub. Date: Nov. 2, 2017

(54) DEVICES INCLUDING DIELECTRIC LAYERS(S) AND INTERFACE LAYERS(S)

(71) Applicant: HEWLETT PACKARD ENTERPRISE DEVELOPMENT LP, Houston, TX (US)

(72) Inventors: Xue Huang, Palo Alto, CA (US); Di Liang, Palo Alto, CA (US)

(21) Appl. No.: 15/141,948

(22) Filed: Apr. 29, 2016

(51) Int. Cl. H01S 5/026; H01S 5/06; H01L 29/94; H01L 29/78; H01L 29/51; H01S 5/30; H01L 29/423

(52) U.S. Cl. CPC H01S 5/0261; H01S 5/3013; H01S 5/06; H01L 29/42364; H01L 29/78; H01L 29/513; H01L 29/94

(57) ABSTRACT

An example device in accordance with an aspect of the present disclosure includes at least one dielectric layer sandwiched between first and second layers, to provide a dielectric characteristic for the device. At least one interface layer, disposed between the at least one dielectric layer and at least one of i) the first layer, and ii) the second layer, is to serve as bond enhancement between the at least one dielectric layer and other layers.

### BACKGROUND

Wafer bonding processes can be used to bond materials together to produce various types of devices. Bonding quality and type of materials used can affect characteristics of a device. Bonding quality can depend on various factors such as interfacial void density, as well as techniques used to bond materials together.

### BRIEF DESCRIPTION OF THE DRAWINGS/FIGURES

FIG. 1 is a block diagram of a device including at least one dielectric layer and at least one interface layer according to an example.

FIG. 2 is a block diagram of a device including at least one dielectric layer and at least one interface layer according to an example.

FIG, 3A is a block diagram of a metal-oxide-semiconductor (MOS) capacitor device including at least one dielectric layer and at least one interface layer according to an example.

FIG. 3B is a block diagram of a metal-oxide-semiconductor field-effect transistor (MOSFET) device including at least one dielectric layer and at least one interface layer according to an example.

FIG. 3C is a block diagram of a Laser integrated device including at least one dielectric layer and at least one interface layer according to an example.

### DETAILED DESCRIPTION

Wafer bonding technology is widely used in integration of different or the same materials. On the bonded platform, different electrical and optical functions can be achieved, including optical waveguide, and MOS capacitor consisting of the two bonded materials with a dielectric layer between them. Desired device characteristics can affect what components are used in the device. For example, a high capacitance MOS capacitor can be obtained by using a dielectric having a high dielectric constant (e.g., a high-k dielectric). As used herein, a value of k can be considered high or low relative to the dielectric constant of silicon dioxide, which is on the order of 3.9. Accordingly, dielectric constants greater than silicon dioxide (3.9) can be considered high-k, and dielectric constants less than silicon dioxide (3.9) can be considered low-k. A high-quality interface between device materials/layers (e.g., between a dielectric and a semiconductor) can enable the device to avoid interface defects, which would otherwise lead to high fixed charge density and reduced performance of the device. However, it can be challenging to obtain high-k dielectric layers on materials compatible with wafer bonding, which may need to be prepared to obtain ultra-smooth dielectric surfaces. This can be difficult, and can be highly affected by the bulk dielectric quality, as well as the dielectric-semiconductor interface quality. Using low-k dielectrics or other layers/materials can pose similar difficulties with other materials, such as obtaining a bond between the dielectric and a semiconductor surface. In some instances, a high-quality interface/bond is not always feasible between a given type of dielectric and a semiconductor material used in the device. In other words, a material having a desired electrical and/or optical property may pose difficulties in terms of being compatible with bonding or other mechanical properties, and vice versa.

To address such issues, examples described herein may optimize electrical and/or optical properties (such as choosing a given material type or layer thickness in a semiconductor-dielectric interface), separately from optimizing mechanical bonding behavior/interfaces. Thus, wafer bonding can be optimized independent of a desired capacitance/optical mode characteristic for a given application (e.g., using a high-k dielectric for MOS applications, or using low-k dielectric/interface layers for optical applications such as photonics). For example, by using multiple different layers of dielectrics, a semiconductor/dielectric interface can be optimized for its electrical properties or as a seed layer to prepare the surface for a different dielectric material on top of it, separate from optimizing the mechanical bonding interface and associated overall device reliability. A given material having a desired electrical or optical property may not provide a desired mechanical property (such as providing a smooth surface for good mechanical bonding). To address this, layering schemes can be used, e.g., multiple layers of different dielectric materials, grown, deposited, or spinned on a given material layer (such as a non-dielectric substrate or semiconductor layer), to provide the desired mechanical bonding properties while retaining the desired electrical properties. It is therefore possible to satisfy device needs while achieving versatile dielectric configurations, without being confined to a single dielectric layer to accommodate the varying desirable properties regarding high interface quality, easy bonding, and high performance capacitor or other electrical/optical properties. In an example implementation, a dielectric scheme can be provided as a dielectric stack configuration optimized for wafer bonding and MOS capacitor applications, including photonic interconnect and other optical applications. Different or similar materials can be bonded via dielectric films, on one or both of surfaces to be bonded together. Such layering schemes facilitate separate optimization of the semiconductor/dielectric interfaces, and the bonding surfaces, to provide versatile options of dielectrics including high-k dielectrics compatible with both high-capacitance MOS application and wafer bonding process, as well as low-k dielectrics compatible with avoiding optical losses.

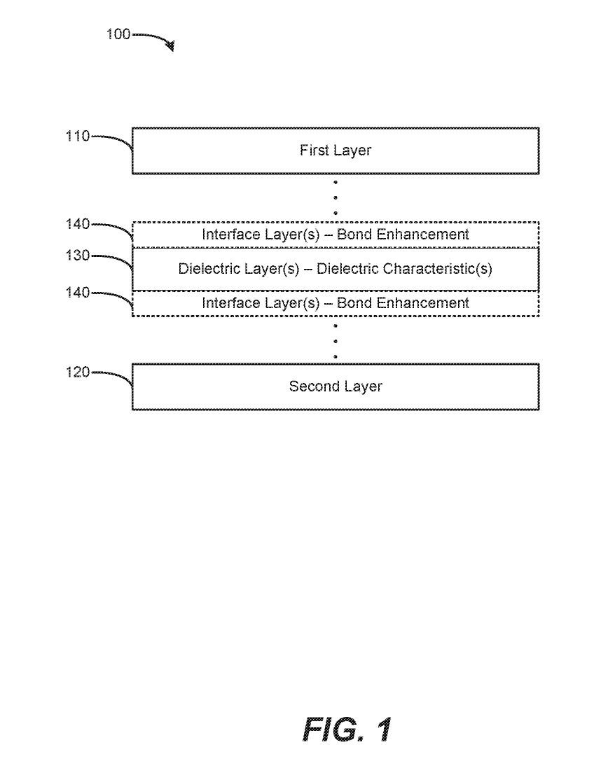

FIG. 1 is a block diagram of a device 100 including at least one dielectric layer 130 and at least one interface layer 140 according to an example. The device 100 also includes a first layer 110 of a first non-dielectric material, and a second layer 120 of a second non-dielectric material (the first and second materials can be different types of materials or the same type of material). The at least one dielectric layer 130 is sandwiched between the first layer 110 and the second layer 120. Although shown as a single block, the at least one dielectric layer 130 can include one or many layers of dielectric materials. The at least one dielectric layer 130 is to provide a dielectric characteristic for the device 100. The at least one interface layer 140 can be disposed between the at least one dielectric layer 130 and at least one of i) the first layer 110, and ii) the second layer 120. The interface layer(s) 140 are to serve as bond enhancement between the at least one dielectric layer 130 and other layers, based on providing low interface state density while increasing surface smoothness and bonding surface energy for the at least one dielectric layer 130. The at least one interface layer 140 is comprised of a dielectric material, which may be the same or different type(s) than the material(s) of the dielectric layer(s) 130.

The dielectric layer(s) 130 can be provided as a versatile dielectric stack that is not limited to a single dielectric layer. The dielectric layer(s) 130 also can be interspersed with one or more interface layers 140. Accordingly, the various layers can accommodate interfaces between layers, providing high quality, easy bonding, and desired capacitance or other electrical characteristics. Various combinations of layers are possible. For example, the first and second layers 110, 120 can be two dissimilar materials to be integrated by wafer bonding. The bonding surface for each of the layers 110, 120 can be provided with a single or multiple dielectric layers 130. The various layers may be chosen for their behavior and properties for opto-electronic devices, and are therefore not limited to having characteristics that might optimize MOS or memory devices (e.g., do not need to have at least one high-k layer). The various layers 110-140 can account for providing desirable optical properties, in conjunction with or as an alternative to, providing specific electrical properties. In some example implementations, the layers 110-140 can be compatible with providing a low-k dielectric, improved and easier bonding, lower costs, and low optical absorption for efficient optical device operations. Accordingly, example implementations of device 100 are compatible with applications such as photonic interconnects, optical sensors, sensing, photonic applications, optics, spectroscopic applications, and the like, whose performance may be affected by the use of high-k and/or low-k layers,

The first layer 110 and second layer 120 can include various materials, such as Si, Ge, SiC, SiGe, SiGeC, InAs, InP, GaAs and other III-V or II-VI compound semiconductors, as well as metals. A first and/or second layer 110, 120 can include layered semiconductors, such as Si/SiGe, silicon-on-insulators (SOis) or silicon germanium-on-insulators (SGOis), III-V-based photodetector, III-V based optical modulator, and III-V-based quantum well or quantum dot laser. The first and second layers 110, 120 can be the formed of the same material as each other. Accordingly, the device 100 can be based on the bonding of two heterogeneous or homogeneous semiconductor materials for the first and second layers 110, 120. By employing the dielectric layers 130 and/or interface layers 140 to provide direct bonding surface(s) between the first and second layers 110, 120, temperatures needed to establish a strong bond are lower than the temperatures otherwise needed for bonding two semiconductor surfaces directly to each other (e.g., without the use of dielectric and/or interface layers 130, 140).

An interface layer 140 is illustrated as being disposed above and/or below the dielectric layer(s) 130, positioned between the dielectric layer(s) 130 and the first layer 110, and/or between the dielectric layer(s) 130 and the second layer 120. A given interface layer(s) 140 can include at least one first interface layer, at least one second interface layer, and so on, between the dielectric layer(s) 130 and the corresponding one of the first and second layers 110, 120. A number of such first and/or second interface layer(s) 140 can be unequally distributed above and/or below the dielectric layer(s) 130. For example, an interface layer 140 can be provided as a layer of dielectric, to prepare a very smooth surface on its corresponding first layer 110 and/or second layer 120. Such interface layers 140 can be chosen for providing a given desired characteristic (e.g., providing mechanical smoothing, dangling-bond passivation, etc. to the first/second layers 110, 120) without a need to satisfy an electrical characteristic. Subsequently, the dielectric layer(s) 130 can be deposited on the interface layer(s) 140 to provide the desirable electrical characteristic (such as high-k) and/or optical characteristics (such as low optical loss) while enjoying the improved mechanical bonding effect provided by the interface layer(s) 140. Furthermore, the cumulative effect of the multiple layers can be synergistic. For example, because the interface layer(s) 140 can provide a very smooth surface, the dielectric layers(s) 130 deposited on the interface layer(s) 140 also assume a smooth configuration, thereby enabling the dielectric layer(s) 130 themselves to providing improved bonding performance (e.g., among different dielectric layer(s) 130) at layer-layer interfaces in the device that may not be in contact with the interface layer(s) 140.

The interface layer(s) 140 thereby provides great flexibility in the combination of possible material choices for other layers, such as the first and/or second layers 110, 120, and the dielectric layers 130. For example, some materials used for dielectric layer(s) 130, when deposited directly onto a semiconductor first/second layer 110, 120, can react with the semiconductor to produce gases byproducts and/or native oxides at the interface, which would result in rough deposition and corresponding poor bond if that material were used alone. The use of interface layer(s) 140 can prevent such poor results, e.g., by acting as a seed layer to enable the use of difficult materials for their desired characteristics, while enabling uniform consistent and smooth deposition of the difficult material. The interface layer(s) 140 also can passivate surface dangling bonds of the layers on which the interface layer(s) 140 is deposited (e.g., first and second layers 110, 120), thereby protecting such layers from negative interactions (e.g., forming native oxide in atmosphere) and providing high interface quality and easy bonding. Accordingly, the at least one interface layer 140 can serve as a seed layer to enable uniform deposition of the at least one dielectric layer 130 onto its corresponding at least one interface layer 140. Additionally, the at least one interface layer 140 is to provide dangling-bond passivation for at least one of the corresponding first and second layers 110, 120 of non-dielectric material.

The dielectric layer(s) 130, and a given interface layer(s) 140, are each illustrated as a single block. However, the illustrated blocks can include multiple layers of the same or different materials. The dielectric layer(s) 130 (as well as the interface layer(s) 140) can be made of various materials such as oxides of hafnium, zirconium, titanium, aluminum, silicon, and the like, as well as silicates, aluminates, titanates, nitrides, and combinations, including multilayered arrangements. Additionally, polymer materials can be used for the dielectric and/or interface layer(s) 130, 140, such as polymethylstyrene, polypropylene oxide, and polymethylmethacrylate. The materials can also include copolymerisations of two or more polymers together for tailored dielectric properties, such as using a copolymer of polyimide with polysiloxane. Polyimide-ceramic composites can be used, such as by incorporating alumina (Al2O3), barium titanate (BaTiO3), titanic (TiO2), and/or zirconia (ZrO2) into a polymer matrix. The dielectric layer(s) 130 can include two or more layers of dissimilar dielectric materials.

The capacitance provided by a given layer can be based on a material type, a material quality, and a material layer thickness. Such qualities can also affect the interface/bond quality. For example, a material type/quality, as well as how the material is layered, can result in a smoother or rougher deposition, which can produce a smaller or larger number of trapped microvoids at inter-layer interfaces, which can strengthen or weaken a physical inter-layer bonding, as well as improve or deteriorate capacitance (which is affected by interface state density and trapped microvoids). Such characteristics can affect performance of the resulting device that is based on such layers.

A desired thicknesses for the interface layer(s) 140 and/or dielectric layer(s) 130 can depend on a type of the layer material, such whether the material is a high-k or low-k dielectric, and the target application of the device, such as capacitor or optical waveguide. For example, when a dielectric material is used to achieve a high capacitance, a thinner layer can be desirable (e.g., on the order of several nanometers), but not so thin to result in undesirably large capacitor leakage current. In some example implementations, a layer can have a thickness of on the order of 0.1 nanometer (nm)-50 nm, or beyond (from sub-nanometer thicknesses to hundreds of nanometers in thickness). The thickness of a given layer can be used to offset or complement material characteristics of the material used to form that layer. For example, when using a high-k material, a relatively large layer thickness can be used to achieve a similar capacitance effect as though a low-k dielectric were used (at a comparably thinner layer thickness). Increased layer thickness can be used to avoid high leakage current, or compensate for other material properties. Very thin layers can also be used to achieve various properties, by reducing layer thicknesses and/or by combining a plurality of thin layers together. The dielectric layer(s) 130 and the interface layer(s) 140 can have thicknesses unequal to each other. The thickness of a given one of a plurality of dielectric layers 130 may be unequal to the others, and a similar principle applies for dielectric layers 130.

The device 100 can thereby provide performance characteristics compatible with use in an opto-electronic device. For example, the use of low-k materials can provide a low-loss waveguide for a target light wavelength (which can include ultraviolet (UV), visible, and/or infrared light). The low-k dielectric can be desirable for some optical wavelengths, as well as for cost savings compared to a high-k dielectric material. Thus, the dielectric layer(s) 130 and the interface layer(s) 140 can be based on low dielectric constant (low-k) material(s), such that the layers 110-140 can exclude the use of a high-k material, thereby providing dielectric characteristics to tune optical modes of the opto-electronic device 100, while providing low optical absorption loss for optical modes overlapping the device. Although not specifically illustrated, optical mode(s) can arise in optical devices, and extend beyond a given layer that is used to generate the optical mode(s).

Various layers, including dielectric layer(s) 130, can be improved using the following techniques. A layer(s) can be treated by pre-deposition cleaning, e.g., Radio Corporation of America (RCA) cleaning, native oxide removal, dangling bond passivation by wet chemicals, and/or by plasma cleaning. Layer(s) can be improved by application of post-deposition thermal annealing to produce dense dielectrics, post-deposition plasma treatment to suppress interfacial void formation, and/or post-bonding annealing to generate large bonding surface energy. The various layers can be produces by plasma-enhanced chemical vapor deposition (PECVD), atomic layer deposition (ALD), sputter deposition, thermal oxidation, ozone oxidation, wet chemical oxidation, native oxide, spin coating, or a combination of one or more approaches. A given bonding surface interface can be provided by similar or dissimilar dielectric or dielectric/semiconductor surfaces.

The device 100 can be built up on a bonded platform, enabling the use of bonded layers. Versatile different layers can be stacked together, to serve different purposes and generate synergistic effects among the plurality of layers 110-140, such as high-yield bonding with low optical loss for desirable device performance. Different combinations of dielectric materials/layers enable the use of materials that may otherwise result in poor bonding and/or performance, which would otherwise prevent the use of such materials in a given application (e.g., photonics). The versatile dielectric stacks enable broad options to optimize aspects such as interfaces between dissimilar materials, smooth bonding surfaces, use of high-k dielectric materials, and the like. The interface between dielectrics and semiconductor materials can benefit from high quality dielectric and low interface defects, and low interface state density, due to the use of interface layer(s) 140. Similarly, smooth bonding surfaces of two dielectric layers (or dielectric and semiconductor layers), e.g., between two sub-layers within the dielectric layer(s) 130, enables high bonding surface energy at a moderate post-bonding annealing temperature. Interface state density, including achieving a relatively low interface state density, can vary from one type of interface to another. Thus, as used herein, the concept of low interface state density corresponds to a given bond, and achieving a relatively lower interface state density for the given bond (e.g., by virtue of use of the interface layer(s) 140, as compared to achieving the bond without the interface layer(s) 140). As an example, for a Si/SiO2 interface, ˜10̂10 cm̂(−2)*eV̂(−1) can be considered to be relatively low interface state density. In contrast, for an InP/oxide interface, a relatively low interface state density can be one or two orders of magnitude higher than that of a Si/SiO2 interface. Thus, low interface state density can beneficially impact applications such as in MOS capacitor performance. For MOS-capacitor applications, the interface layer(s) 140 enable the use of high-k dielectrics including (but not limited to) HfO2, ZrO2, TiO2, and Al2O3, which are desirable to obtain high capacitance but may not be ideal for bonding characteristics (absent the interface layer(s) 140).

Thus, first/second layers 110, 120 can be provided as doped heterogeneous or homogeneous semiconductor materials, having dielectric layer(s) 130 sandwiched in between. The dielectric layer(s) 130 and/or the interface layer(s) 140 can serve as a bonding interface, and can also function as e.g., an insulation layer of a MOS capacitor. Dielectrics with high dielectric constant k or low dielectric constant k can be introduced, while achieving low void density by virtue of the interface layer(s) 140 or appropriate layer of dielectric layer(s) 130 (e.g., if a dielectric layer is directly bonded to the first and/or second layer 110, 120). The use of dielectric schemes can provide heterogeneous integration by bonding technology to optimize the semiconductor/dielectric interfaces, separate from the optimization of bonding surfaces, providing multiple techniques of optimizing a given device.

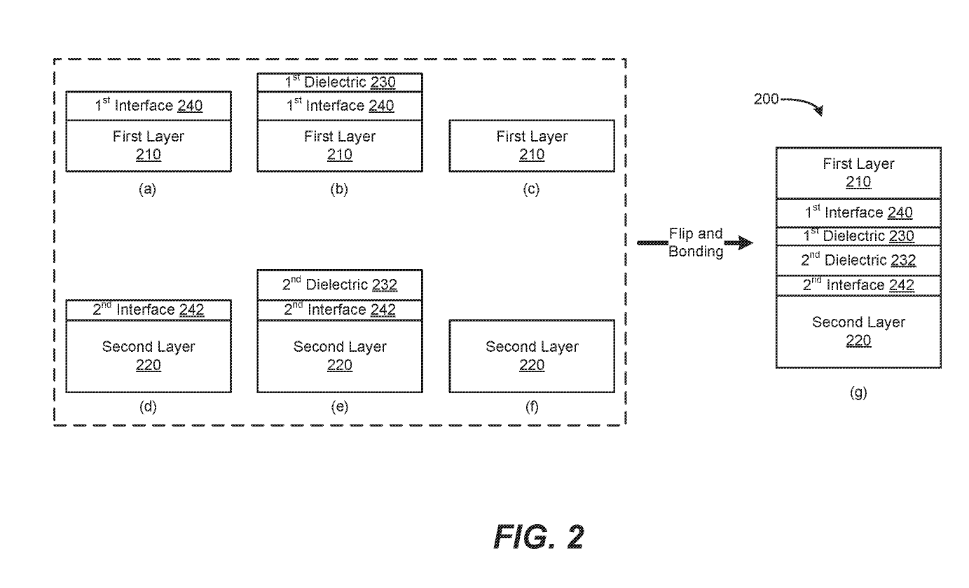

FIG. 2 is a block diagram of a device 200 including at least one dielectric layer 230, 232, and at least one interface layer 240, 242 according to an example. Such layers are sandwiched between the first layer 210 and the second layer 220. Various example combinations of layers are shown in blocks (a)-(f), and the device 200 is shown as block (g) formed as a combination of block (b) and (e). In block (a), a bonding surface of the first layer 210 has a single first interface layer 240, e.g., formed by a dielectric material. In block (b), the bonding surface of the first layer 210 has multiple layers of dielectric materials, shown FIG. 2 as a specific scenario having two different layers, the first dielectric layer 230 and the first interface layer 240. In block (c), the bonding surface of the first layer 210 has no dielectric layer. In block (d), the bonding surface of the second layer 220 has a single dielectric layer, second interface layer 242. In block (e), the bonding surface of the second layer 220 has multiple layers of dielectric material, shown as second interface layer 242 and second dielectric layer 232. In block (f), the bonding surface of the second layer 220 has no dielectric layer. Such blocks are merely one example implementation, and other such implementations are possible (e.g., having more than two layers, which may be formed of different or similar materials).

In the example implementation of FIG. 2, the first layer 210 and the second layer 220 are shown as two dissimilar materials. Similarly, other first materials in block (b) to represent the first dielectric layer 230 and the first interface layer 240 can be dissimilar from respective materials in block (e) corresponding to the second dielectric layer 232 and the second interface layer 242. Accordingly, a given device 200 can be formed without needing to have the same material coming in contact together, e.g., different materials can be used for the first and second dielectric layers 230 and 232 bonded together in block (g). Possible combinations for wafer bonding include (a) and (d), (a) and (e), (a) and (f), (b) and (d), (b) and (e), (b) and (f), (c) and (d), (c) and (e). Such combinations can be extended for other example implementations, e.g., combining three or more layers onto the first and/or second layers 210, 220 to form a given block, which then may be bonded together.

Device 200 is shown in block (g) having a balanced distribution of four layers between the first and second layers 210, 220. In alternate example implementations, the various layers can be distributed unequally per side between the first layer 210 and the second layer 220 among the sub-blocks that are bonded together. A number of layers can be extended greatly, such as more than ten layers, according to various desired characteristics and cumulative or synergistic effects on wafer bonding and electrical/optical performance. The various layers also can be based on different thicknesses of materials and/or on different types of materials. As illustrated, the first and second interface layers 240, 242 are different thicknesses, the first and second dielectric layers 230, 232 are different thicknesses, and the first and second layers 210, 220 are different thicknesses. A given dielectric layer can be based on more than two layers, and a given interface layer can be based on two or more layers, resulting in more than four layers disposed between the first and second layers 210, 220.

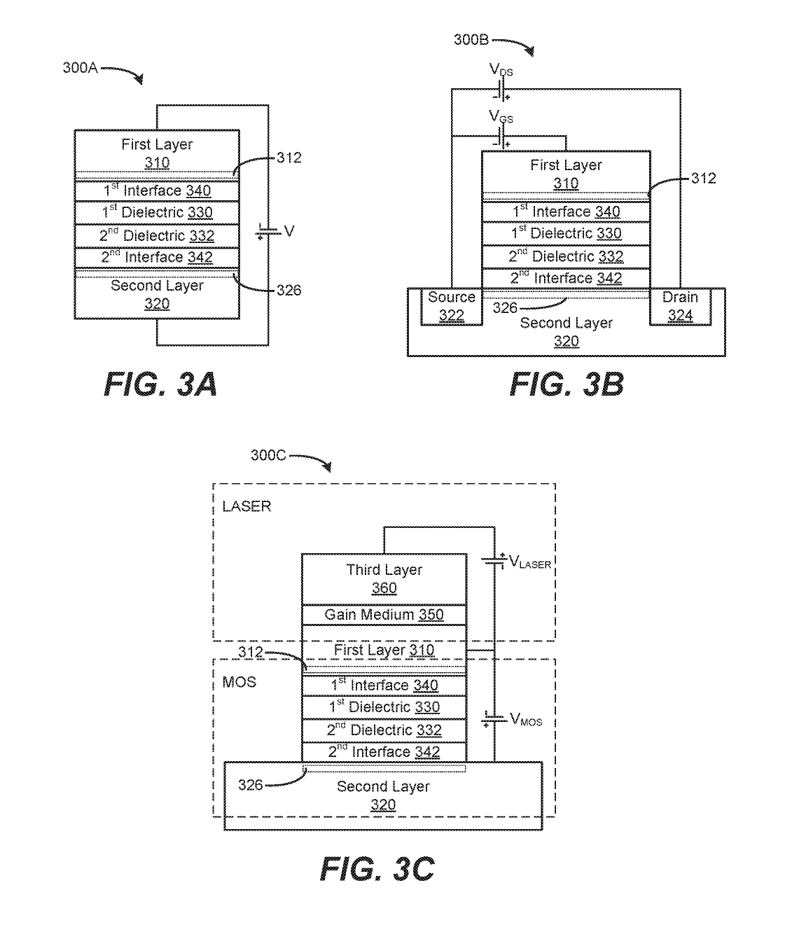

FIGS. 3A-3C illustrate various applications of the versatile dielectric schemes for wafer bonding as described herein. For illustrative purposes, an example implementation similar to FIG. 2 (illustrating two dual-layer dielectric stacks on each side) has been used in each of the devices of FIGS. 3A-3C. The example devices can be operated/biased according to different conditions/voltages, such that regimes 312, 326 can serve as accumulation, depletion, or inversion regimes according to the different operational modes being used (e.g., under different specific bias voltages). Thus, operation of devices 300A-300C is not limited to accumulation regimes, and also includes operation according to the depletion regime and inversion regime.

FIG. 3A is a block diagram of a metal-oxide-semiconductor (MOS) capacitor device 300A including at least one dielectric layer 330, 332 and at least one interface layer 340, 342 according to an example. The first and second layers 310, 320 can be various materials, including semiconductors. The first semiconductor material and the second semiconductor material include respective accumulation/depletion/inversion regimes 312, 326 to support carrier distribution in the device 300A. When operated according to the illustrated applied voltage V, the regimes 312, 326 can operate as accumulation regimes. Similar regime principles also apply to FIGS. 3B and 3C. The dielectric stack bonding of FIG. 3A can be operated as a MOS capacitor in the accumulation regime as illustrated, or in the depletion regime or inversion regime, depending on the bias voltage V.

FIG. 3B is a block diagram of a metal-oxide-semiconductor field-effect transistor (MOSFET) device 300B including at least one dielectric layer 330, 332 and at least one interface layer 340, 342 according to an example. The device 300B illustrates an n-type MOS field effect transistor (MOSFET), with the inverted MOS providing a continuous conducting path between the source 322 and drain 324 regions, as well as controlling the current between them. The MOSFET is provided by wafer bonding of layers 310, 340, 330 and layers 332, 342, 320, with the carrier distribution in the inversion regime.

FIG. 3C is a block diagram of a Laser integrated device 300C including at least one dielectric layer 330, 332 and at least one interface layer 340, 342 according to an example. A III-V device (LASER) is shown wafer bonded on silicon (MOS), so light can be generated in the III-V device, then coupled to the silicon. The dielectric stack is provided between the III-V device and the silicon to form a capacitor. The capacitor formed by layers 310-342 overlaps with optical modes of the LASER (e.g., as generated by the gain medium 350 as influenced by the first and third layers 310, 360). The capacitor formed by layers 310-342 can then be used to tune the optical modes of the device 300C. Accordingly, the capacitor can be used to attract or deplete charges, and change optical properties, e.g., optical refractive index and absorption loss, to tune the device 300C and corresponding emission wavelength and optical power of the LASER. The first layer 310 serves as a doped semiconductor layer for the integrated LASER structure, while also serving as a doped semiconductor layer for the metal-oxide semiconductor (MOS) capacitor structure of layers 310-342. As for the dielectric layer(s) 330, 332 and interface layer(s) 340, 342, optical low-loss waveguide effect can be achieved for a given target light wavelength (such as ultraviolet (UV), visible, and/or infrared light) based on the use of low-k dielectrics, which can be desirable for some optical wavelengths. However, the device 300C is not limited to the use of low-k materials. For example, the formed MOS capacitor can be used to tune optical refractive index and optical loss, based on the use of high-k dielectrics to enhance the tuning range. It is also possible to reduce some of the tuning capability of the capacitor, by using a low-k dielectric, because the low-k dielectric provides benefits of lower optical loss for the light wavelengths used. Accordingly, the dielectric layer(s) 330, 332 can provide the dielectric characteristics compatible with optical modes that are to at least partially overlap the device 300C. The optical modes are associated with wavelengths on the order of approximately 10 nanometers to 1 millimeters, and a scheme of dielectric layer(s) and interface layer(s) is based on a given wavelength for the device and achieving low optical loss in view of the given wavelength. Further, the formed capacitor of layers 310-342 can be used to tune the optical refractive index and optical loss, where high-k dielectrics can be preferred. The regimes 312, 326 are shown in accumulation regimes of the MOS structure based on the applied voltages. Laser optical mode(s) (not shown in the schematic) are generated via applied V_{LASER}, and carrier distribution changes are caused by V_{MOS}, providing laser resonant wavelength tuning as well as loss tuning.

1. A device comprising:
a first layer of a first non-dielectric material;
a second layer of a second non-dielectric material;
at least one dielectric layer sandwiched between the first layer and the second layer, to provide a dielectric characteristic for the device;
at least one interface layer, disposed between the at least one dielectric layer and at least one of i) the first layer, and ii) the second layer, to provide increased surface smoothness and bonding surface energy for the at least one dielectric layer, wherein the at least one interface layer is comprised of a dielectric material; and
wherein the at least one interface layer includes at least one first interface layer between the first layer and the at least one dielectric layer, and at least one second interface layer between the at least one dielectric layer and the second layer.

2. The device of claim 1, wherein the device is for use in an opto-electronic device, and the at least one dielectric layer and the at least one interface layer comprise low dielectric constant (low-k) material(s) that does not include a high-k material, to provide low optical absorption loss for optical modes overlapping the device.

3. The device of claim 1, wherein the at least one dielectric layer comprises two or more layers of dissimilar dielectric materials.

4. The device of claim 1, wherein the at least one dielectric layer comprises at least one layer of a polymer material.

5. The device of claim 1, wherein the at least one interface layer serves as a seed layer to enable uniform deposition of the at least one dielectric layer onto its corresponding at least one interface layer.

6. The device of claim 1, wherein the at least one interface layer is to provide passivation for at least one of the corresponding first and second layers of non-dielectric material.

7. (canceled)

8. The device of claim 1, wherein a number of the at least one first interface layer(s) is not equal to a number the at least one second interface layer(s).

9. The device of claim 1, wherein thicknesses of the at least one dielectric layer(s) and the at least one interface layer(s) are unequal to each other.

10. A device comprising:
a first layer of a first semiconductor material;
a second layer of a second semiconductor material;
at least one dielectric layer sandwiched between the first layer and the second layer, to provide a dielectric characteristic for the device;
at least one interface layer, disposed between the at least one dielectric layer and at least one of i) the first layer, and ii) the second layer, to provide increased surface smoothness and bonding surface energy for the at least one dielectric layer; and
wherein the at least one interface layer includes at least one first interface layer between the first layer and the at least one dielectric layer, and at least one second interface layer between the at least one dielectric layer and the second layer.

11. The device of claim 10, wherein the first semiconductor material and the second semiconductor material include respective accumulation, depletion, and inversion regimes to support carrier distribution in the device.

12. An opto-electronic device comprising:
a first layer of a first non-dielectric material;
a second layer of a second non-dielectric material;
at least one low-k dielectric layer sandwiched between the first layer and the second layer, to provide a dielectric characteristic for the device;
at least one interface layer, disposed between the at least one dielectric layer and at least one of i) the first layer, and ii) the second layer, to provide increased surface smoothness and bonding surface energy for the at least one dielectric layer, wherein the at least one interface layer is comprised of a low-k dielectric material; and
wherein the at least one interface layer includes at least one first interface layer between the first layer and the at least one dielectric layer, and at least one second interface layer between the at least one dielectric layer and the second layer.

13. The device of claim 12, wherein the first layer serves as a doped multilayer semiconductor for an integrated laser structure, while also serving as a doped semiconductor layer for a metal-oxide semiconductor capacitor structure.

14. The device of claim 12, wherein the at least one dielectric layer is to provide the dielectric characteristic in the form of a capacitor usable to change optical properties including a refractive index and optical loss of the device, based on tuning optical modes that are to at least partially overlap the capacitor when the optical modes are generated by operation of the device.

15. The device of claim 14, wherein the optical modes are associated with wavelengths on the order of approximately 10 nanometers to 1 millimeters, and a scheme of dielectric layer(s) and interface layer(s) is based on a given wavelength for the device and achieving low optical loss in view of the given wavelength.
